(19) United States
(12) Patent Application Publication
(10) Pub. No.: US 2026/0362906 A1
(43) Pub. Date: Nov. 12, 2026

(54) DISPLAY DEVICE, METHOD OF MANUFACTURING DISPLAY DEVICE, AND ELECTRONIC DEVICE

(71) Applicant: Samsung Display Co., Ltd., Yongin-si (KR)

(72) Inventor: Jaehoon Kim, Yongin-si (KR)

(21) Appl. No.: 19/446,036

(22) Filed: Jan. 12, 2026

(30) Foreign Application Priority Data
May 9, 2025 (KR) 10-2025-0060563

(51) Int. Cl. H10K 59/122; H10K 59/12; H10K 59/123; H10K 102/00

(52) U.S. Cl. CPC H10K 59/122; H10K 59/1201; H10K 59/123; H10K 2102/351

(57) ABSTRACT

A display device includes a base substrate, a transistor structure provided over the base substrate, a pixel electrode electrically connected to the transistor structure over the base substrate, a pixel definition layer, a light emitting unit provided over the pixel definition layer and the pixel electrode, and an opposite electrode provided over the light emitting unit. The pixel definition layer includes an opening overlapping the pixel electrode over the base substrate. The pixel definition layer may include a lower pixel definition layer including a first photosensitive resin, an upper pixel definition layer stacked over the lower pixel definition layer and including a second photosensitive resin that is different from the first photosensitive resin, and an interface layer between the lower pixel definition layer and the upper pixel definition layer. The interface layer may have a roughness of about 1.5 Å to about 20 Å, as measured by X-ray reflectometry.

### CROSS-REFERENCE TO RELATED APPLICATION

The present application claims priority to and the benefit of Korean Patent Application No. 10-2025-0060563, filed on May 9, 2025, in the Korean Intellectual Property Office, the entire content of which is hereby incorporated by reference.

### BACKGROUND

### 1. Field

One or more embodiments of the present disclosure relate to a display device, a method of manufacturing the display device, and an electronic device. For example, one or more embodiments relate to a display device including a light emitting unit, a pixel definition layer, and electrodes, a method of manufacturing the display device, and an electronic device including the display device.

### 2. Description of the Related Art

In a display device such as an organic light emitting diode (OLED) display device and a liquid crystal display (LCD) device, a display substrate includes, for example, a thin film transistor (TFT) and various suitable types or kinds of lines. A display structure including a light emitting unit and electrodes may be formed over the display substrate.

A pixel area may include a red pixel area, a green pixel area, and a blue pixel area, and electrical characteristics from each pixel area may affect image display quality.

### SUMMARY

One or more embodiments of the present disclosure include a display device having improved electrical characteristics and display characteristics.

One or more embodiments include an electronic device including a display device having improved electrical characteristics and display characteristics.

Additional aspects of embodiments will be set forth in part in the description which follows and, in part, will be apparent from the description, or may be learned by practice of the presented embodiments of the disclosure.

According to one or more embodiments, a display device includes a base substrate, a transistor structure provided over the base substrate, a pixel electrode electrically connected to the transistor structure over the base substrate, a pixel definition layer, a light emitting unit provided over the pixel definition layer and the pixel electrode, and an opposite electrode provided over the light emitting unit. The pixel definition layer includes an opening overlapping the pixel electrode over the base substrate. The pixel definition layer may include a lower pixel definition layer including a first photosensitive resin, an upper pixel definition layer stacked over the lower pixel definition layer and including a second photosensitive resin different from the first photosensitive resin, and an interface layer between the lower pixel definition layer and the upper pixel definition layer. The interface layer may have a roughness of about 1.5 Å to about 20 Å, as measured by X-ray reflectometry.

In some embodiments, the roughness of the interface layer, as measured by the X-ray reflectometry, may be about 2 Å to about 10 Å.

In some embodiments, the thickness of the interface layer, as measured by the X-ray reflectometry, may be about 10 Å to about 200 Å.

In some embodiments, the thickness of the interface layer, as measured by the X-ray reflectometry, may be about 20 Å to about 100 Å.

In some embodiments, the interface layer may include a blend of the first photosensitive resin and the second photosensitive resin.

In some embodiments, the first photosensitive resin may include a polyimide resin.

In some embodiments, the second photosensitive resin may include an acrylic resin.

In some embodiments, the pixel definition layer may include a wrinkle structure provided at each of an upper surface of the upper pixel definition layer and a side surface of the upper pixel definition layer.

In some embodiments, the wrinkle structure may not be provided at a side surface of the lower pixel definition layer.

In some embodiments, a side surface of the upper pixel definition layer and a side surface of the lower pixel definition layer may be on a same plane in the opening.

In some embodiments, the side surface of the upper pixel definition layer, the side surface of the lower pixel definition layer, and a side surface of the interface layer may be on a same plane in the opening.

According to one or more embodiments, a method of manufacturing a display device includes forming a pixel electrode over a base substrate, forming a lower insulating layer (e.g., a lower electrically insulating layer) by applying a first photosensitive resin composition to cover the pixel electrode, forming an upper insulating layer (e.g., an upper electrically insulating layer) by applying a second photosensitive resin composition over the lower insulating layer, forming an exposed portion and a non-exposed portion in each of the upper insulating layer and the lower insulating layer by partially exposing the upper insulating layer and the lower insulating layer together, forming an opening exposing an upper surface of the pixel electrode, by removing the exposed portions or the non-exposed portions included in the upper insulating layer and the lower insulating layer together, forming a light emitting unit over the pixel electrode, and forming an opposite electrode over the light emitting unit.

In some embodiments, the forming of the lower insulating layer may include forming a first pre-cured layer by pre-baking the applied first photosensitive resin composition.

In some embodiments, the forming of the upper insulating layer may include forming a second pre-cured layer by pre-baking the applied second photosensitive resin composition.

In some embodiments, an interface layer may be formed between the lower insulating layer and the upper insulating layer as the second photosensitive resin composition is applied over the lower insulating layer.

In some embodiments, after the opening is formed, the upper insulating layer and the lower insulating layer having the exposed portion or the non-exposed portion removed therefrom may be post-baked together.

In some embodiments, the post-baking may include forming an upper pixel definition layer and a lower pixel definition layer from the upper insulating layer and the lower insulating layer with the exposed portion or the non-exposed portion removed therefrom, respectively.

In some embodiments, the post-baking may include forming a wrinkle structure at each of an upper surface of the upper pixel definition layer and a side surface of the upper pixel definition layer.

In some embodiments, the first photosensitive resin composition and the second photosensitive resin composition may include a same solvent.

According to one or more embodiments, an electronic device includes a display device, a memory, and a processor configured to control an operation of the display device by executing data included in the memory. The display device includes a base substrate, a transistor structure provided over the base substrate, a pixel electrode electrically connected to the transistor structure over the base substrate, a pixel definition layer, a light emitting unit provided over the pixel definition layer and the pixel electrode, and an opposite electrode provided over the light emitting unit. The pixel definition layer includes an opening overlapping the pixel electrode over the base substrate. The pixel definition layer may include a lower pixel definition layer including a first photosensitive resin, an upper pixel definition layer stacked over the lower pixel definition layer and including a second photosensitive resin different from the first photosensitive resin, and an interface layer between the lower pixel definition layer and the upper pixel definition layer. The interface layer may have a roughness of about 1.5 Å to about 20 Å, as measured by X-ray reflectometry.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic plan view of a display device according to embodiments;

FIG. 2 is an equivalent pixel circuit diagram of a display device according to embodiments;

FIGS. 3 to 5 are schematic cross-sectional views illustrating a display device according to embodiments;

FIG. 6 is a schematic cross-sectional view illustrating a light emitting element of a display device according to embodiments;

FIGS. 7 to 18 are schematic cross-sectional views illustrating a method of manufacturing a display device according to embodiments;

FIG. 19 is an exploded perspective view illustrating an electronic device according to embodiments;

FIG. 20 is a block diagram of an electronic device according to an embodiment;

FIG. 21 is a schematic diagram of electronic devices according to embodiments;

FIGS. 22 and 23 are schematic cross-sectional views illustrating a method of manufacturing a display device according to a comparative example;

FIG. 24 is a surface image of pixel definition layers according to an embodiment and a comparative example;

FIG. 25 is an image illustrating surface contact angles of pixel definition layers according to an embodiment and a comparative example; and

FIG. 26 is an image illustrating surface repellencies of pixel definition layers according to an embodiment and a comparative example.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Hereinafter, embodiments will be described in more detail with reference to the accompanying drawings. In embodiments, the same reference numerals will be used for the same components in the drawings, and redundant descriptions of the same components may not be repeated for conciseness. The embodiments illustrated in the accompanying drawings are merely examples and should be understood as including all modifications, equivalents, or substitutes included in the spirit and scope of the disclosure.

Terms such as “on”, “connected”, and “coupled” used herein include not only direct arrangement/connection/coupling but also embodiments where one or more other components are therebetween.

Terms such as “first”, “second”, “under”, “lower”, “over”, and “upper” are used as relative concepts to distinguish different components or positions and do not specify absolute positions or orders.

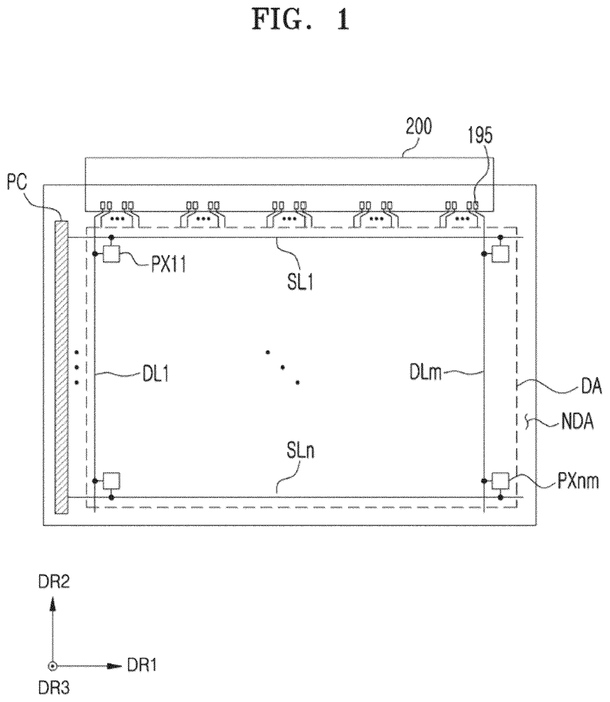

FIG. 1 is a schematic plan view of a display device according to embodiments.

In FIG. 1, a first direction DR1 and a second direction DR2 may refer to two directions that are parallel (e.g., substantially parallel) to a display surface of the display device and are perpendicular (e.g., substantially perpendicular) to each other. For example, the first direction DR1 may correspond to an X direction (row direction or widthwise direction) of the display device, and the second direction DR2 may correspond to a Y direction (column direction or lengthwise direction) of the display device. A third direction DR3 may be perpendicular (e.g., substantially perpendicular) to the first direction DR1 and the second direction DR2. The third direction DR3 may correspond to a Z direction (thickness direction) of the display device.

The above definitions of the directions may be equally applied to the following drawings.

Referring to FIG. 1, a plurality of pixels PX11 to PXnm may be provided in a display area DA of the display device.

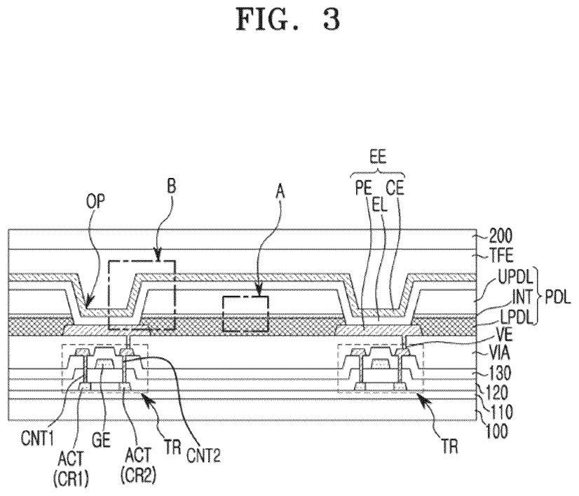

According to embodiments, a pixel circuit including scan lines (or gate lines) SL1 to SLn forming first to nth rows and data lines DL1 to DLm forming first to mth columns may be provided over a base substrate 100 (see FIG. 3) of the display device. Each of the pixels PX11 to PXnm may be connected to a corresponding nth-row scan line among the gate lines SL1 to SLn and a corresponding mth-column data line among the data lines DL1 to DLm.

Each of the pixels PX11 to PXnm may further include a light emitting element and a pixel driving/switching element including a transistor as described below. In embodiments, the pixel circuit may further include lines such as a power line and a ground line.

FIG. 1 illustrates that the data lines DL1 to DLm extend in the second direction DR2 and the scan lines SL1 to SLn extend in the first direction DR1; however, the disclosure is not necessarily limited thereto.

A peripheral circuit PC may be provided in a non-display area NDA corresponding to a peripheral area with respect to the display area DA. For example, the peripheral circuit PC may include a gate driving circuit. The gate driving circuit may be integrated into the display device through an oxide semiconductor gate (OSG) driving circuit process, an amorphous silicon gate (ASG) driving circuit process, or a polysilicon gate (PSG) driving circuit process.

The peripheral circuit PC may further include a data driver, a gate driver, a light emitting driver, a power voltage generator, and a timing controller.

The display device may further include a printed circuit board 200. Pad units 195 of the pixel circuit may be assembled to one side portion of the non-display area NDA. The printed circuit board 200 may be electrically connected to the pixel circuit through the pad units 195. For example, the printed circuit board 200 may be electrically connected to the pad units 195 through a heat-pressing process using a conductive mediation structure (e.g., an electrically conductive mediation structure) such as an anisotropic conductive film (ACF).

An integrated circuit (IC) such as a data driving circuit may be provided over the printed circuit board 200. In some embodiments, an IC chip may be mounted on the printed circuit board 200 in the form of a chip-on-film (COF).

Hereinafter, the configuration/structures of the display device of the disclosure may be described by using an organic light emitting display device as an example. However, the display device described herein may also be applied to various suitable types or kinds of display devices such as an inorganic light emitting display device and a quantum dot light emitting display device.

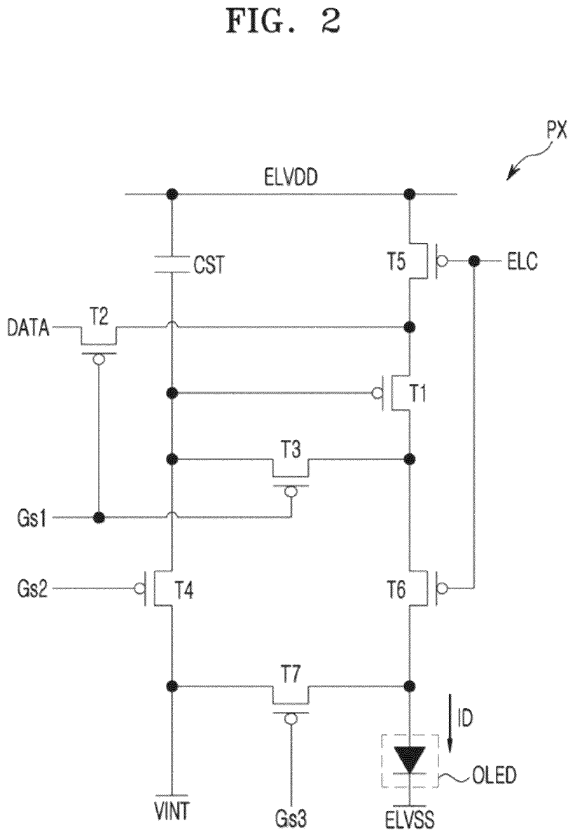

FIG. 2 is an equivalent pixel circuit diagram of a display device according to embodiments.

Referring to FIG. 2, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal, and a second terminal. The gate terminal may be connected to the storage capacitor CST. The first terminal may be connected to the second transistor T2. The second terminal may be connected to the sixth transistor T6. The first transistor T1 may generate a driving current ID based on the voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive a first gate signal Gs1. The second transistor T2 may be turned on or off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal, and a second terminal. The gate terminal may receive the first gate signal Gs1. The first terminal may be connected to the gate terminal of the first transistor T1. The second terminal may be connected to the second terminal of the first transistor T1. The third transistor T3 may compensate for the threshold voltage of the first transistor T1. For example, the third transistor T3 may be provided as a compensation transistor.

The fourth transistor T4 may include a gate terminal, a first terminal, and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal, and a second terminal. The gate terminal may receive an emission control signal ELC. The first terminal may receive a high-power voltage ELVDD. The second terminal may be connected to the first transistor T1.

The sixth transistor T6 may include a gate terminal, a first terminal, and a second terminal. The gate terminal may receive the emission control signal ELC. The first terminal may be connected to the first transistor T1. The second terminal may be connected to an organic light emitting diode OLED. The sixth transistor T6 may be configured to transmit the driving current ID to the organic light emitting diode OLED in response to the emission control signal ELC.

The seventh transistor T7 may include a gate terminal, a first terminal, and a second terminal. The gate terminal may receive a third gate signal Gs3. The first terminal may be connected to the organic light emitting diode OLED. The second terminal may receive the initialization voltage VINT. The seventh transistor T7 may initialize the organic light emitting diode OLED.

The storage capacitor CST may include a first terminal and a second terminal. The first terminal may receive the high-power voltage ELVDD. The second terminal may be connected to the gate terminal of the first transistor T1.

The organic light emitting diode OLED may include a first terminal and a second terminal. The first terminal may be connected to the sixth transistor T6. The second terminal may receive a low power voltage ELVSS. The organic light emitting diode OLED may emit light based on the driving current ID.

Although FIG. 2 illustrates a 7T1C structure including seven thin film transistors and one storage capacitor CST per pixel PX, the pixel structure of the display device described herein is not necessarily limited thereto.

For example, each pixel PX may include two or more transistors and may have a structure such as 2T1C, 3T2C, 5T2C, or 6T2C.

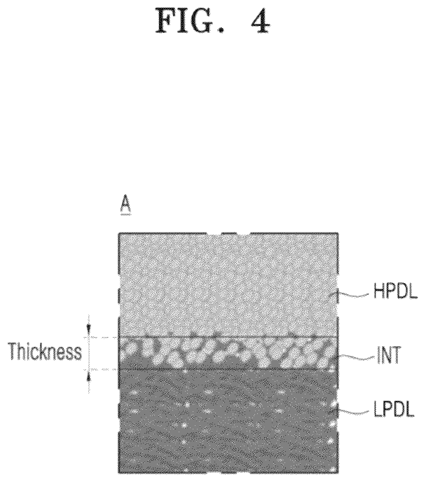

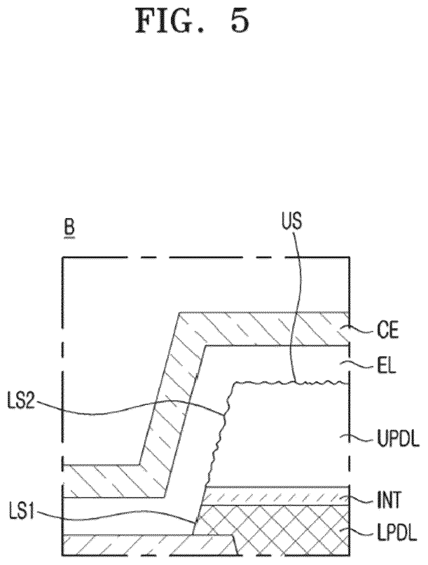

FIGS. 3 to 5 are schematic cross-sectional views illustrating a display device according to embodiments. FIG. 4 is an enlarged cross-sectional view of region A of FIG. 3. FIG. 5 is an enlarged cross-sectional view of region B of FIG. 3.

Referring to FIG. 3, the display device may include transistor structures TR provided over a base substrate 100, and a pixel electrode PE electrically connected to each of the transistor structures TR.

The base substrate 100 may be provided as a back-plane substrate or a support substrate of the display device. A glass substrate and/or a plastic substrate (e.g., a polymer substrate) may be used as the base substrate 100.

In some embodiments, the base substrate 100 may include a polymer material having transparency and flexibility. In embodiments, the base substrate 100 may be used in a transparent flexible display device. For example, the base substrate 100 may include a polymer material such as polyimide, polysiloxane, an epoxy-based resin, an acrylic resin, and/or polyester. In an embodiment, the base substrate 100 may include polyimide.

A buffer layer 110 may be on the upper surface of the base substrate 100. Penetration of moisture through the base substrate 100 may be blocked or reduced by the buffer layer 110, and diffusion of impurities between the base substrate 100 and the structure over the base substrate 100 may be blocked or reduced.

The buffer layer 110 may be provided entirely across the display area DA and the non-display area NDA of the base substrate 100 and may entirely cover the upper surface of the base substrate 100.

The buffer layer 110 may include, for example, an inorganic insulating material (e.g., an inorganic electrically insulating material) such as silicon oxide, silicon nitride, and/or silicon oxynitride. These materials may be used alone or in combination. In some embodiments, the buffer layer 110 may have a stack structure including a silicon oxide layer and a silicon nitride layer. The buffer layer 110 may be formed through a deposition process such as a chemical vapor deposition (CVD) process, a sputtering process, and/or an atomic layer deposition (ALD) process to include the above inorganic insulating material.

Transistor structures TR may be provided over the buffer layer 110. The transistor structures TR may be electrically connected to the pixel electrode PE.

The transistor structure TR may include an active layer ACT, a gate insulating layer 120 (e.g., a gate electrically insulating layer 120), and a gate electrode GE. The transistor structure TR may further include contact electrodes CNT1 and CNT2 connected to the active layer ACT.

The active layer ACT may be provided over the buffer layer 110 and may be patterned, for example, through a photolithography process, to be repeatedly/regularly provided in each pixel area. The active layer ACT may include a silicon compound such as polysilicon. Some areas of the active layer ACT may be doped with a p-type dopant or an n-type dopant and may include a source region, a drain region, and a channel region.

The active layer ACT may include an oxide semiconductor such as indium gallium zinc oxide (IGZO), zinc tin oxide (ZTO), or indium tin zinc oxide (ITZO).

The gate insulating layer 120 may be provided over the active layer ACT, and the gate electrode GE may be stacked over the gate insulating layer 120. The gate insulating layer 120 may extend continuously (e.g., substantially continuously) across a plurality of pixel areas and may be commonly included in a plurality of transistor structures TR.

In embodiments, the gate insulating layer 120 may partially cover each active layer ACT and may be provided in an independent pattern shape in each of the transistor structures TR.

The gate electrode GE may overlap the channel region of the active layer ACT in the third direction DR3 (thickness direction). A scan signal may be transmitted from a scan line through the gate electrode GE.

The gate insulating layer 120 may be formed through the above deposition process to include an inorganic insulating material (e.g., an inorganic electrically insulating material) such as silicon oxide, silicon nitride, silicon oxynitride, and/or metal oxide.

In some embodiments, a p-type dopant or an n-type dopant may be implanted into the active layer ACT through an ion implantation process using the gate electrode GE as an ion implantation mask. Accordingly, a first contact region CR1 and a second contact region CR2 may be provided at one side portion and the other side portion of the active layer ACT, respectively. The first contact region CR1 and the second contact region CR2 may respectively correspond to a source region and a drain region.

A portion of the active layer ACT, which is between the first contact region CR1 and the second contact region CR2 and overlaps the gate electrode GE in the third direction DR3 (thickness direction), may be defined as a channel region.

In some embodiments, the gate insulating layer 120 may be provided as a pattern covering the channel region through an etching process using the gate electrode GE as an etch mask. If (e.g., when) the active layer ACT includes an oxide semiconductor, if (e.g., when) an interlayer insulating layer 130 (e.g., an interlayer electrically insulating layer 130) is formed, hydrogen (H) included in the interlayer insulating layer 130 may be diffused and/or moved to the active layer ACT. Accordingly, the carrier concentration may increase due to hydrogen, and contact regions CR1 and CR2 may be provided at the side portions of the active layer ACT.

The interlayer insulating layer 130 covering the gate insulating layer 120 and the gate electrode GE may be provided over the active layer ACT. The interlayer insulating layer 130 may be formed through the above deposition process to include an inorganic insulating material (e.g., an inorganic electrically insulating material) such as silicon oxide, silicon nitride, and/or silicon oxynitride. The interlayer insulating layer 130 may have a single-layer structure or a multilayer structure including different materials.

A contact electrode (CNT1, CNT2) contacting or electrically connected to the active layer ACT may be provided over the interlayer insulating layer 130.

The contact electrode may include a first contact electrode CNT1 connected to or contacting the first contact region CR1 of the active layer ACT and a second contact electrode CNT2 connected to or contacting the second contact region CR2 of the active layer ACT. The first contact electrode CNT1 and the second contact electrode CNT2 may be respectively provided as a source electrode and a drain electrode.

According to embodiments, the interlayer insulating layer 130 may be partially etched to form contact holes. For example, contact holes respectively exposing the first contact region CR1 and the second contact region CR2 may be formed. A metal layer suitably or sufficiently filling the contact holes may be formed over the interlayer insulating layer 130 through a deposition process such as a sputtering process, and then, the metal layer may be partially etched to form the first contact electrode CNT1 and the second contact electrode CNT2. For example, a data signal may be transmitted from a data line through the first contact electrode CNT1.

The gate electrode GE and the contact electrodes CNT1 and CNT2 may include a metal such as Ag, Mg, Al, W, Cu, Ni, Cr, Mo, Ti, Pt, Ta, Nd, and/or Sc, any suitable alloy thereof, and/or any nitride thereof. The gate electrode GE and the contact electrodes CNT1 and CNT2 may be formed through a deposition process such as a sputtering process.

The gate electrode GE and the contact electrodes CNT1 and CNT2 may have a multilayer structure (e.g., a Ti layer, an Al layer, and a Ti layer).

A via insulating layer VIA (e.g., a via electrically insulating layer VIA) covering the contact electrodes CNT1 and CNT2 may be provided over the interlayer insulating layer 130. The via insulating layer VIA may be substantially provided as a planarization layer of a thin film transistor (TFT)-array.

The via insulating layer VIA may be partially etched to form a via hole exposing the upper surface of the contact electrode (e.g., the second contact electrode CNT2). An electrode layer suitably or sufficiently filling the via hole may be provided on the upper surface of the via insulating layer VIA, and then, the electrode layer may be partially etched to form the pixel electrode PE.

The pixel electrode PE may include a via electrode portion VE provided in the via insulating layer VIA. The pixel electrode PE may be electrically connected to each of the transistor structures TR through the via electrode portion VE.

The via insulating layer VIA may be provided as an organic insulating layer (e.g., an organic electrically insulating layer). For example, the via insulating layer VIA may include an organic polymer material such as polyimide, an epoxy-based resin, an acrylic resin, polyester, a siloxane-based resin, and/or benzocyclobutene (BCB). For example, the via insulating layer VIA may be formed through a coating process such as a spin coating process.

The pixel electrode PE may be provided as an anode and may include a high-work-function conductive material (e.g., electrically conductive material) that promotes hole injection. The pixel electrode PE may be provided as a transparent electrode. The pixel electrode PE may include a transparent conductive oxide such as indium tin oxide (ITO), indium zinc oxide (IZO), zinc oxide (ZnO), and/or indium tin zinc oxide (ITZO).

The pixel electrode PE may also be provided as a semitransparent electrode or a reflective electrode. The pixel electrode PE may include a metal selected from among Ag, Mg, Cu, Al, Pt, Pd, Au, Ni, Nd, Ir, Cr, Li, Ca, LiF, Mo, Ti, W, In, Sn, and Zn, and/or any suitable alloy thereof.

The pixel electrode PE may have a single-layer structure or a multilayer structure. For example, the pixel electrode PE may have a three-layer structure of ITO/Ag/ITO and/or ITO/AI/ITO.

A pixel definition layer PDL exposing the upper surface of each of the pixel electrodes PE may be formed over the via insulating layer VIA. The pixel definition layer PDL may fill the space between the pixel electrodes PE and cover a peripheral portion of the pixel electrode PE.

The pixel definition layer PDL may include an opening OP overlapping the center portion of the pixel electrode PE. For example, the upper surface of the pixel electrode PE may be exposed by the opening OP. An emission area or a pixel area may be substantially defined by the opening OP.

A light emitting unit EL may be provided over the pixel definition layer PDL and the pixel electrode PE.

The pixel definition layer PDL may be provided in the form of a partition wall that fills the space between adjacent pixel electrodes PE. FIG. 3 illustrates that the pixel definition layer PDL has a trapezoidal partition wall form having a forward-tapered shape; however, the disclosure is not limited thereto. For example, the pixel definition layer PDL may be provided in a trapezoidal partition wall form having a rectangular reverse-tapered shape.

According to embodiments, the pixel definition layer PDL may include an inorganic insulating material (e.g., an inorganic electrically insulating material). For example, the pixel definition layer PDL may include a photosensitive resin such as a polysiloxane resin, a polyimide resin, an acrylic resin, and/or an epoxy-based resin. The pixel definition layer PDL may include a multilayer structure.

According to embodiments, the pixel definition layer PDL may include a lower pixel definition layer LPDL including a first photosensitive resin and an upper pixel definition layer UPDL including a second photosensitive resin that is different from the first photosensitive resin.

The lower pixel definition layer LPDL may fill the space between adjacent pixel electrodes PE, and an end portion of the lower pixel definition layer LPDL may overlap a peripheral portion of the pixel electrode PE. For example, the end portion of the lower pixel definition layer LPDL may partially contact the upper surface of the pixel electrode PE.

The upper pixel definition layer UPDL may be provided over the lower pixel definition layer LPDL. For example, the upper pixel definition layer UPDL may be on the upper surface of the lower pixel definition layer LPDL. The lower surface of the upper pixel definition layer UPDL may directly contact the upper surface of the lower pixel definition layer LPDL.

For example, the pixel definition layer PDL may be entirely in the peripheral portion of the pixel electrode PE around (e.g., to surround) the pixel electrode PE.

According to embodiments, an interface layer INT may be formed between the lower pixel definition layer LPDL and the upper pixel definition layer UPDL. For example, the interface layer INT may have a set or certain thickness.

Referring to FIG. 4, the interface layer INT may include a blend of the first photosensitive resin and the second photosensitive resin. For example, the interface layer INT may represent an area in which the first photosensitive resin and the second photosensitive resin may be intermixed at the interface between the lower pixel definition layer LPDL and the upper pixel definition layer UPDL.

The thickness of the interface layer INT may represent the thickness-direction length of an area in which the first photosensitive resin and the second photosensitive resin are intermixed.

In embodiments, the roughness of the interface layer INT, as measured by X-ray reflectometry, may be about 1.5 Å to about 20 Å. In the above range, the morphology of the surface of the pixel definition layer PDL may increase or improve and thus improved repellency may be provided.

In an embodiment, the roughness of the interface layer INT may be measured by using an X-ray reflectivity (XRR) measuring device. An example of the XRR measuring device may be the D8 ADVANCE Plus from Bruker Corporation, but the present disclosure is not limited thereto.

The thickness, density, and interface roughness of a single-layer thin film or a multilayer thin film including two or more layers may be measured by using the XRR measuring device.

For example, if (e.g., when) X-rays are irradiated to the thin film, a path difference may be formed with respect to the reflection from the upper surface and lower surface of the thin film and thus constructive or destructive interference may occur. Thus, the roughness of the interface may be measured by measuring the reduced reflection intensity (reflectivity) of the X-rays compared to the total reflection.

For example, if (e.g., when) the roughness of the interface layer INT exceeds 20 Å, the surface uniformity of the pixel definition layer PDL may be excessively degraded. Thus, if (e.g., when) the light emitting unit EL contacts the upper surface and/or side surface of the pixel definition layer PDL, the light emitting unit EL may have nonuniform light emitting characteristics.

For example, if (e.g., when) the roughness of the interface layer INT is less than 1.5 Å, the repellency of the pixel definition layer PDL may be excessively degraded. Thus, if (e.g., when) the light emitting unit is formed by applying an organic light emitting material, the residue of the organic light emitting material may increase.

In some embodiments, the roughness of the interface layer INT may be about 2 Å to about 15 Å, about 2 Å to about 10 Å, about 2.5 Å to about 8 Å, or about 3 Å to about 5 Å. In the above ranges, the repellency of the pixel definition layer PDL may be improved and uniform (e.g., substantially uniformly) light emitting characteristics may be provided and thus a high-reliability display device may be provided.

In some embodiments, the thickness of the interface layer INT may be about 10 Å to about 200 Å, about 15 Å to about 150 Å, about 20 Å to about 100 Å, or about 30 Å to about 50 Å. In the above ranges, the first photosensitive resin and the second photosensitive resin may be suitably or sufficiently intermixed and thus the morphology of the pixel definition layer PDL may be suitably or sufficiently improved.

In some embodiments, the first photosensitive resin and the second photosensitive resin may include the same type or kind of photosensitive resin selected from among a positive-type photosensitive resin and a negative-type photosensitive resin.

For example, each of the first photosensitive resin and the second photosensitive resin may include a positive-type photosensitive resin. In embodiments, the exposed portion may be dissolved and removed by a developer.

Each of the first photosensitive resin and the second photosensitive resin may include a negative-type photosensitive resin. In embodiments, the non-exposed portion may be dissolved and removed by a developer.

For example, the lower pixel definition layer LPDL may directly contact the pixel electrode PE. Thus, a resin having improved chemical stability may be provided as the first photosensitive resin.

In some embodiments, the first photosensitive resin may include a polyimide resin.

For example, the upper pixel definition layer UPDL may include a second photosensitive resin that is different from the first photosensitive resin included in the lower pixel definition layer LPDL. Thus, during curing, wrinkles may be formed in the upper pixel definition layer UPDL due to the shrinkage rate difference between the photosensitive resins.

In some embodiments, the second photosensitive resin may include an acrylic resin. The acrylic resin may include any suitable acrylic resin generally used in the art. Examples of the acrylic resin may include polymethylacrylate, polymethylmethacrylate, and polybutylacrylate.

Referring to FIG. 5, a wrinkle structure may be formed at least partially on the surface of the pixel definition layer PDL.

In some embodiments, the pixel definition layer PDL may include a wrinkle structure formed at each of an upper surface US of the upper pixel definition layer UPDL and a side surface LS2 of the upper pixel definition layer UPDL.

For example, the wrinkle structure may be provided entirely across the upper surface US and the side surface LS2 of the upper pixel definition layer UPDL. For example, the wrinkle structure may indicate that fine unevenness is formed at the surface (e.g., may provide fine unevenness at the surface).

Accordingly, because the repellency of the upper surface US and the side surface LS2 may be improved, if (e.g., when) ink is applied, the remaining of residue of the ink on the upper surface US and the side surface LS2 may be suppressed or reduced.

In an embodiment, the wrinkle structure may not be substantially formed at the side surface LS1 of the lower pixel definition layer LPDL. For example, the repellency of the side surface LS1 of the lower pixel definition layer LPDL may be lower than the repellency of each of the upper surface US and the side surface LS2 of the upper pixel definition layer UPDL. Accordingly, the ink may be stably applied in the opening of the pixel definition layer PDL.

In some embodiments, the side surface LS2 of the upper pixel definition layer UPDL and the side surface LS1 of the lower pixel definition layer LPDL may be on the same plane in the opening OP. For example, the inner surface of the upper pixel definition layer UPDL and the inner surface of the lower pixel definition layer LPDL may form a continuous surface (e.g., a substantially continuous surface).

In an embodiment, the side surface LS2 of the upper pixel definition layer UPDL, the side surface LS1 of the lower pixel definition layer LPDL, and the side surface of the interface layer INT may be on the same plane in the opening OP.

Referring back to FIG. 3, the light emitting unit EL may be provided over the pixel electrode PE and the pixel definition layer PDL. For example, the light emitting unit EL may fill the opening of the pixel definition layer PDL and partially overlap the upper surface of the pixel definition layer PDL.

In an embodiment, the light emitting unit EL may extend continuously (e.g., substantially continuously) and commonly across a plurality of pixels. In embodiments, the light emitting unit EL may include a white emission layer or a blue emission layer.

An opposite electrode CE may be provided over the light emitting unit EL. The opposite electrode CE may be a common electrode that is provided commonly and continuously (e.g., substantially continuously) across a plurality of pixel areas.

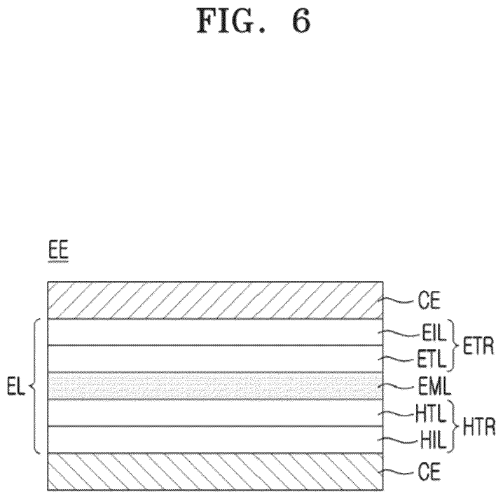

A light emitting element EE including the light emitting unit EL will be described below in more detail with reference to FIG. 6.

The opposite electrode CE may be provided as an electron injection electrode or a cathode. The opposite electrode CE may include a metal, an alloy, and/or an electrically conductive compound having a low work function.

For example, the opposite electrode CE may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, and/or IZO. These materials may be used alone or in combination.

The opposite electrode CE may be provided as a transparent electrode, a semitransparent electrode, or a reflective electrode. The opposite electrode CE may have a single-layer structure or a multilayer structure.

The opposite electrode CE may be formed through a deposition process such as a sputtering process using a target including the conductive material (e.g., the electrically conductive material) described above.

The light emitting element EE may be defined by the pixel electrode PE, the light emitting unit EL, and the opposite electrode CE described above. The light emitting element EE may be provided as an organic light emitting diode (OLED) element.

An encapsulation layer TFE may be provided over the opposite electrode CE. The encapsulation layer TFE may be provided over the pixel definition layer PDL and the light emitting elements EE to protect the light emitting elements EE from moisture and/or oxygen.

The encapsulation layer TFE may include an inorganic layer including silicon nitride (SiNₓ), silicon oxide (SiOₓ), indium tin oxide, indium zinc oxide, and/or any suitable combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethyl methacrylate and/or polyacrylic acid), an epoxy-based resin (e.g., aliphatic glycidyl ether (AGE)), or any suitable combination thereof; or a combination of an inorganic layer and an organic layer.

The encapsulation layer TFE may have a single-layer or multilayer structure. In some embodiments, the encapsulation layer TFE may have a sequential stack structure of a first inorganic layer, an organic layer, and a second inorganic layer.

In some embodiments, a color control layer overlapping the light emitting unit EL may be provided over the encapsulation layer TFE. The color control layer may include a color filter and/or a color conversion layer including quantum dots.

In some embodiments, a sensor layer such as a touch sensor layer and/or an optical functional layer such as a polarization plate, an anti-reflection layer, and/or an anti-static layer may be provided over the encapsulation layer TFE.

FIG. 6 is a schematic cross-sectional view illustrating a light emitting element of a display device according to embodiments.

Referring to FIG. 6, the light emitting element EE may include a pixel electrode PE, an opposite electrode CE, and a light emitting unit EL between the pixel electrode PE and the opposite electrode CE as described above.

The light emitting unit EL may include a hole transport layer HTL, an emission layer EML, and an electron transport layer ETL. According to embodiments, the hole transport layer HTL, the emission layer EML, the electron transport layer ETL, and the opposite electrode CE may be sequentially stacked from the upper surface of the pixel electrode PE.

The emission layer EML may include an organic light emitting material having red, green, or blue light emitting characteristics. For example, the emission layer EML may include a fluorescent host and/or a host for a phosphorescent element and may further include a fluorescent dopant, a phosphorescent dopant, and/or a thermally activated delayed fluorescence (TADF) dopant.

For example, the hole transport layer HTL may include a hole transport material such as m-MTDATA (4,4′,4″-[tris(3-methylphenyl)phenylamino] triphenylamine), TDATA (4,4′4″-tris(N, N-diphenylamino)triphenylamine), 2-TNATA (4,4′,4″-tris[N (2-naphthyl)-N-phenylamino]-triphenylamine), NPB (N,N′-di(naphthalene-I-yl)-N, N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), and/or PEDOT/PSS (poly(3,4-ethylenedioxythiophene)/poly(4-styrenesulfonate)).

For example, the electron transport layer ETL may include an electron transport material such as an anthracene-based compound, Alq₃ (tris(8-hydroxyquinolinato)aluminum), TPBi (1,3,5-Tri (1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), and/or BAlq (bis(2-methyl-8-quinolinolato-N1,O8)-(1,1′-biphenyl-4-olato)aluminum).

In some embodiments, the hole transport layer HTL and the electron transport layer ETL may be provided as a common layer that extends continuously (e.g., substantially continuously) across a plurality of pixel areas.

In some embodiments, a hole injection layer HIL may be further between the pixel electrode PE and the hole transport layer HTL. The hole transport layer HTL and the hole injection layer HIL may be provided as a hole transport region HTR. An electron injection layer EIL may be further between the opposite electrode CE and the electron transport layer ETL. The electron transport layer ETL and the electron injection layer EIL may be provided as an electron transport region ETR.

The layers included in the light emitting unit EL may be formed through thermal deposition, evaporation deposition, vacuum deposition, spin coating, inkjet printing, laser printing, casting, laser thermal transfer, and/or the like.

For example, the emission layer EML may be formed by applying and drying an organic light emitting material on the pixel definition layer PDL and the pixel electrode PE (e.g., inkjet printing).

According to embodiments, the surface repellency of the pixel definition layer PDL may be improved and thus the remaining of residue of the organic light emitting material on the surface of the pixel definition layer PDL may be suppressed or reduced. Thus, a high-reliability light emitting element EE may be provided.

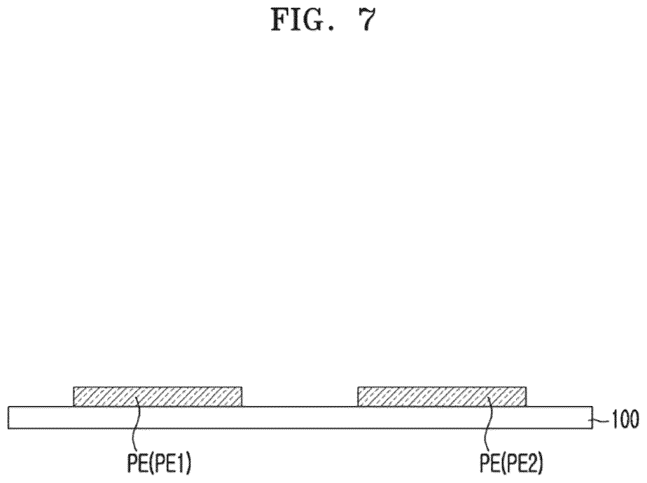

FIGS. 7 to 18 are schematic cross-sectional views illustrating a method of manufacturing a display device according to embodiments. For example, FIGS. 7 to 18 are schematic cross-sectional views illustrating a method of manufacturing the display device described with reference to FIG. 3.

In FIGS. 7 to 18, detailed illustration of the structures and components between the base substrate 100 and the pixel electrode PE are omitted for convenience of illustration and description.

Referring to FIG. 7, pixel electrodes PE1 and PE2 may be formed over a base substrate 100 as described with reference to FIG. 3.

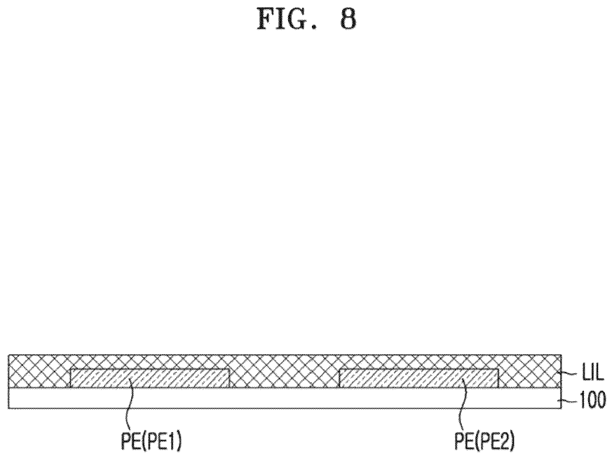

Referring to FIG. 8, as described with reference to FIG. 3, a lower insulating layer LIL (e.g., a lower electrically insulating layer LIL) may be formed by applying a first photosensitive resin composition to cover the pixel electrodes PE1 and PE2.

In some embodiments, the forming of the lower insulating layer LIL may include forming a first pre-cured layer by applying and then pre-baking the first photosensitive resin composition. For example, the lower insulating layer LIL may be entirely formed over the base substrate 100 to cover the pixel electrode PE.

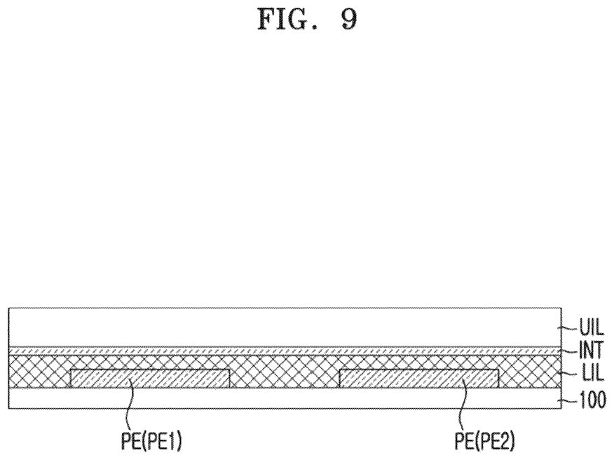

Referring to FIG. 9, an upper insulating layer UIL (e.g., an upper electrically insulating layer UIL) may be formed by applying a second photosensitive resin composition on the lower insulating layer LIL. For example, the upper insulating layer UIL may be entirely formed over the first pre-cured layer.

As described with reference to FIGS. 3 and 4, an interface layer INT may be formed between the lower insulating layer LIL and the upper insulating layer UIL.

In some embodiments, the forming of the upper insulating layer UIL may include forming a second pre-cured layer by applying and then pre-baking a second photosensitive resin composition.

The first photosensitive resin composition may include a first solvent and the first photosensitive resin described above with reference to FIG. 3. The second photosensitive resin composition may include a second solvent and the second photosensitive resin described above with reference to FIG. 3. For example, the first solvent and the second solvent may be dried and removed if (e.g., when) the lower insulating layer LIL and the upper insulating layer UIL are post-baked.

For example, each of the first solvent and the second solvent may independently include a general solvent included in the photosensitive resin composition. Examples of the solvents may include propylene glycol monoethyl ether acetate, ethoxypropionate ethyl, butylacetic acid, ethylene glycol monomethyl ether acetate, propylene glycol monomethyl ether, propylene glycol methyl ether acetate, diethylene glycol dimethyl ether, diethylene glycol methyl ethyl ether, cyclohexanone, 3-methoxypropionate ethyl, and 3-ethoxypropionate methyl.

The first photosensitive resin composition and the second photosensitive resin composition may include the same solvent or different solvents.

In an embodiment, the first solvent and the second solvent may be provided as the same solvent. Accordingly, the first photosensitive resin composition and the second photosensitive resin composition may be more easily intermixed at the interface layer INT. Thus, if (e.g., when) the upper insulating layer UIL is cured, the roughness of the interface layer INT may be controlled such that the thickness of the interface layer INT is within the above ranges.

Each of the first photosensitive resin composition and the second photosensitive resin composition may independently further include a dye, a pigment, a solvent, and/or a surfactant within a range that does not hinder the characteristics of the compositions.

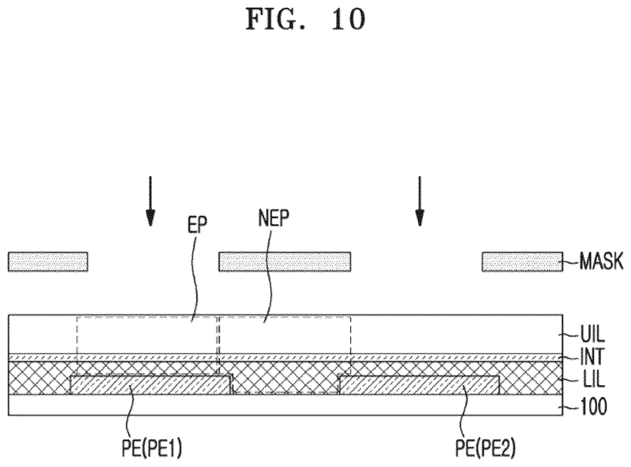

Referring to FIG. 10, an exposed portion EP and a non-exposed portion NEP may be formed in each of the upper insulating layer UIL and the lower insulating layer LIL by partially exposing the upper insulating layer UIL and the lower insulating layer LIL together.

In some embodiments, a photomask MASK may be provided over the upper insulating layer UIL to partially expose the upper insulating layer UIL and the lower insulating layer LIL.

For example, the upper insulating layer UIL and the lower insulating layer LIL may be concurrently (e.g., simultaneously) exposed. Also, because one photomask MASK is used for the upper insulating layer UIL and the lower insulating layer LIL, the inner surfaces of the non-exposed portions NEP of the upper insulating layer UIL and the lower insulating layer LIL may be on the same plane if (e.g., when) viewed in the plane direction.

The partial exposing of the upper insulating layer UIL and the lower insulating layer LIL may include partially exposing the interface layer INT to form an exposed portion EP and a non-exposed portion NEP at the interface thereof.

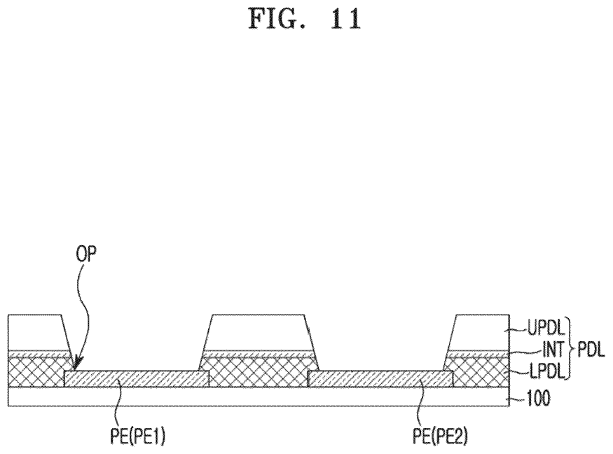

Referring to FIG. 11, an opening OP exposing the upper surface of the pixel electrode PE may be formed by removing the exposed portion EP or the non-exposed portion NEP. An upper pixel definition layer UPDL may be formed by removing the exposed portion EP or the non-exposed portion NEP of the upper insulating layer UIL. A lower pixel definition layer LPDL may be formed by removing the exposed portion EP or the non-exposed portion NEP of the lower insulating layer LIL. Thus, a pixel definition layer PDL including an opening OP may be formed as described with reference to FIG. 3.

For example, the removing of the exposed portion EP or the non-exposed portion NEP may be performed through a development process. For example, the development process may be performed by using an alkaline developer such as tetramethyl ammonium hydroxide (TMAH) and/or potassium hydroxide (KOH).

For example, if (e.g., when) each of the first photosensitive resin and the second photosensitive resin is provided as a positive-type photosensitive resin, the exposed portion EP may be dissolved and removed by the developer.

If (e.g., when) each of the first photosensitive resin and the second photosensitive resin is provided as a negative-type photosensitive resin, the unexposed portion NEP may be dissolved and removed by the developer.

Although FIG. 11 illustrates that the exposed portion EP is removed, the unexposed portion NEP may be removed. In embodiments, the photomask MASK may be provided at a portion that overlaps the pixel electrode PE in the thickness direction of the display device.

In embodiments, after the exposed portion EP or the unexposed portion NEP is removed to form the opening OP, the upper insulating layer UIL and the lower insulating layer LIL may be post-baked together. For example, a heat treatment process by post-baking may be performed at a temperature of, for example, about 150 °C to about 350 °C. Accordingly, the second solvent and the first solvent may be dried and removed from the upper insulating layer UIL and the lower insulating layer LIL, respectively.

For example, wrinkles may be formed at the upper insulating layer UIL due to the shrinkage rate difference between the first photosensitive resin and the second photosensitive resin in the mixing area in the curing process. Thus, a set or certain roughness may be formed at the interface between the upper pixel definition layer UPDL and the lower pixel definition layer LPDL.

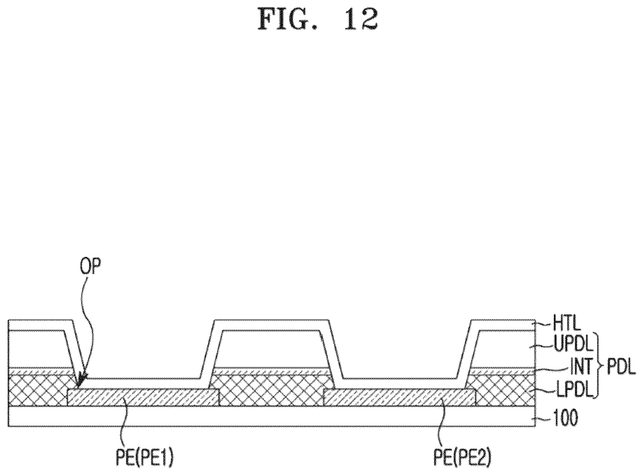

Referring to FIGS. 12 to 14, as described with reference to FIG. 3, a light emitting unit EL may be formed over the pixel definition layer PDL and the pixel electrode PE.

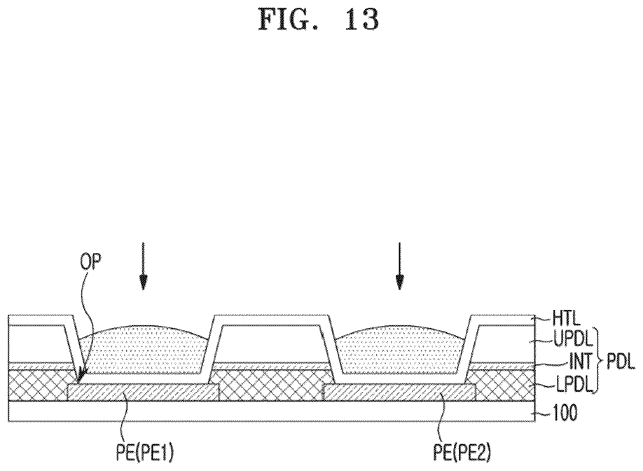

As illustrated in FIG. 13, an emission layer EML may be formed by applying an organic light emitting material to fill the opening OP of the pixel definition layer PDL. For example, because the pixel definition layer PDL has improved surface repellency, the organic light emitting material may be stably dispersed in the opening OP.

As illustrated in FIG. 12, a hole transport layer HTL may be formed over the pixel electrode PE and the pixel definition layer PDL before forming the emission layer EML.

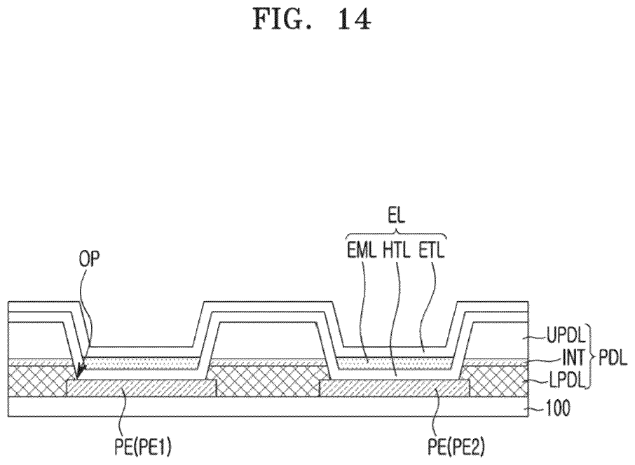

As illustrated in FIG. 14, an electron transport layer ETL may be formed over the emission layer EML.

The hole transport layer HTL and the electron transport layer ETL may be formed through thermal deposition, evaporation deposition, vacuum deposition, spin coating, inkjet printing, laser printing, casting, laser thermal transfer, and/or the like.

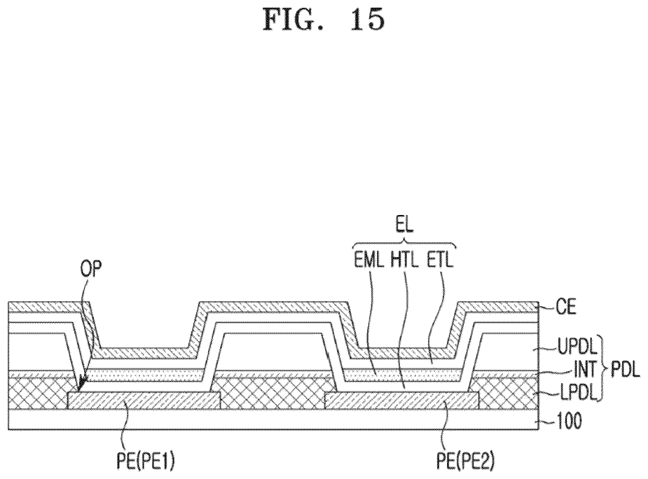

Referring to FIG. 15, as described with reference to FIG. 3, an opposite electrode CE may be formed over the light emitting unit EL.

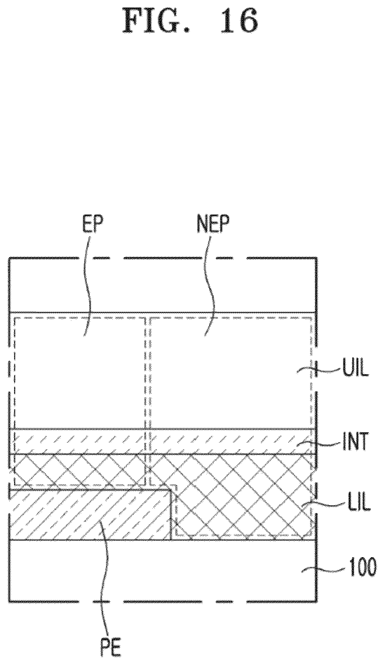

FIGS. 16 to 18 are enlarged views illustrating a method of forming the above wrinkle structure according to embodiments. In FIGS. 16 to 18, redundant descriptions of the same components as those described with reference to FIGS. 10 and 11 may not be repeated for conciseness.

Referring to FIG. 16, as described with reference to FIG. 10, if (e.g., when) forming the upper insulating layer UIL over the lower insulating layer LIL, a wrinkle structure may not be formed on the upper surface of the upper insulating layer UIL.

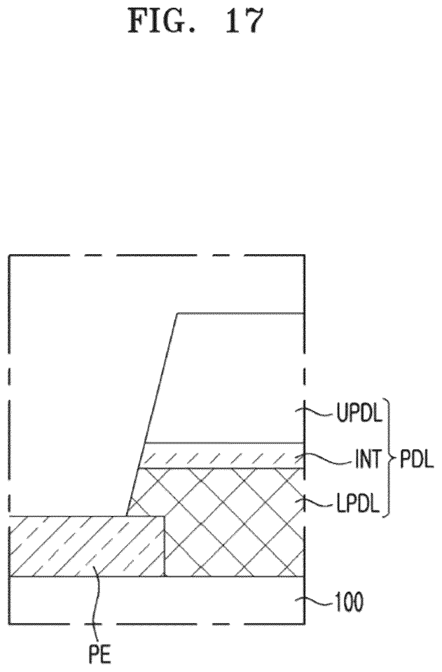

Referring to FIG. 17, as described with reference to FIG. 11, if (e.g., when) providing the photomask MASK on the upper surface of the upper insulating layer UIL and performing exposure and development, a wrinkle structure may not be formed on the upper surface of the upper insulating layer UIL.

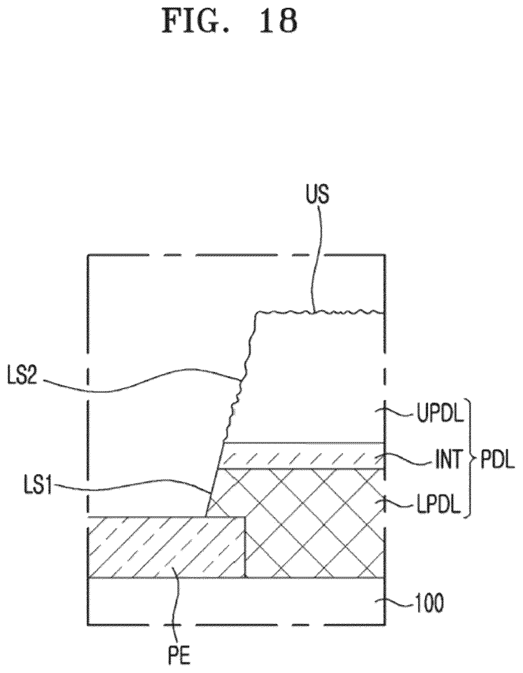

Referring to FIG. 18, by the post-baking, a wrinkle structure may be formed at each of the upper surface US and the side surface LS2 of the upper pixel definition layer UPDL.

As described with reference to FIG. 10, an upper pixel definition layer UPDL and a lower pixel definition layer LPDL may be formed by post-baking the upper insulating layer UIL and the lower insulating layer LIL with the exposed portion EP or the non-exposed portion NEP removed therefrom.

For example, the first photosensitive resin included in the lower insulating layer LIL and the second photosensitive resin included in the upper insulating layer UIL may have different shrinkage rates in the heat treatment.

In some embodiments, the shrinkage rate of the second photosensitive resin may be lower or higher than the shrinkage rate of the first photosensitive resin. In an embodiment, the shrinkage rate of the second photosensitive resin may be higher than the shrinkage rate of the first photosensitive resin. In an embodiment, the shrinkage rate of the second photosensitive resin may be lower than the shrinkage rate of the first photosensitive resin.

For example, by the post-baking, the photosensitive resins may be shrunk and/or cured by polymerization and/or cross-linking. In embodiments, a wrinkle structure may be formed due to compressive stress occurring in the upper layer due to the shrinkage rate difference between the first photosensitive resin and the second photosensitive resin in the interface layer INT.

Thus, a wrinkle structure may be selectively formed at the upper surface US and the side surface LS2 of the upper pixel definition layer UPDL, and the wrinkle structure may not be substantially formed at the side surface LS1 of the lower pixel definition layer LPDL.

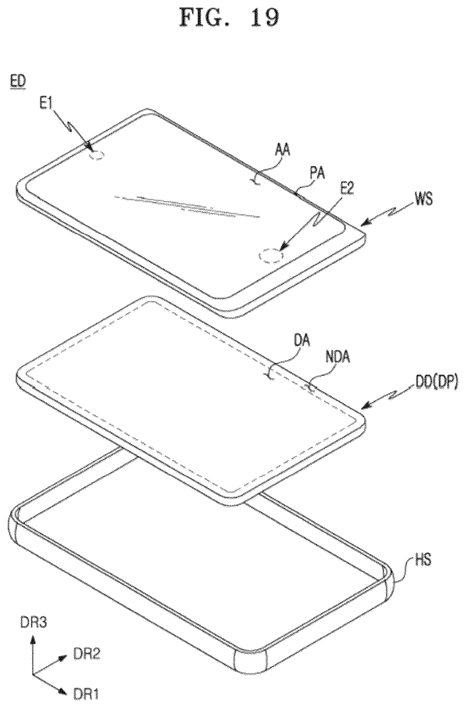

FIG. 19 is an exploded perspective view illustrating an electronic device according to embodiments.

According to embodiments, an electronic device ED may be implemented in the form of a mobile phone (or a smartphone), a tablet personal computer (PC), and/or the like including the display device described above.

Referring to FIG. 19, the electronic device ED may include a window structure WS, a display device DD, and a housing HS. The display device DD may include a display panel DP including the transistor and the light emitting element described above. The housing HS, the display device DD, and the window structure WS may be sequentially stacked in the third direction.

For example, the window structure WS may provide an external display surface recognized by the user, such as a viewing surface of an electronic device such as a mobile phone, and may include a transparent material film. For example, the window structure WS may include glass (e.g., ultra-thin glass (UTG)), a hard coating film, and/or a plastic film (e.g., a polymer film).

The outer surface of the window structure WS may include an active area AA and a peripheral area PA. The active area AA may provide a surface on which an image of the display device DD is actually displayed and on which a user's touch/command is input. The peripheral area PA may substantially correspond to a bezel area of the electronic device ED.

The display device DD or the display panel DP may include a display area DA and a non-display area NDA. The display area DA of the display panel DP may substantially correspond to or overlap the active area AA of the window structure WS.

The non-display area NDA of the display panel DP may substantially correspond to or overlap the peripheral area PA of the window structure WS. The peripheral area PA of the window structure WS may further include a margin area that does not overlap the non-display area NDA of the display panel DP.

In some embodiments, functional element areas E1 and E2 may be included in the active area AA of the window structure WS. For example, a first functional element area E1 may be included in one end portion of the active area AA and may be implemented in the form of, for example, a camera hole. A second functional element area E2 may be provided as a fingerprint sensing area.

For example, a sensor structure for touch sensing and/or fingerprint sensing may be provided in the display panel DP and/or between the window structure WS and the display panel DP.

The housing HS may be provided as a support frame and/or a rear housing of the display device DD or the electronic device ED. A cover panel may be between the housing HS and the display panel DP. The housing HS or the cover panel may include a plate (e.g., a SUS plate) that supports the display panel DP. The housing HS or the cover panel may include an elastomer for shock absorption of the display device DD.

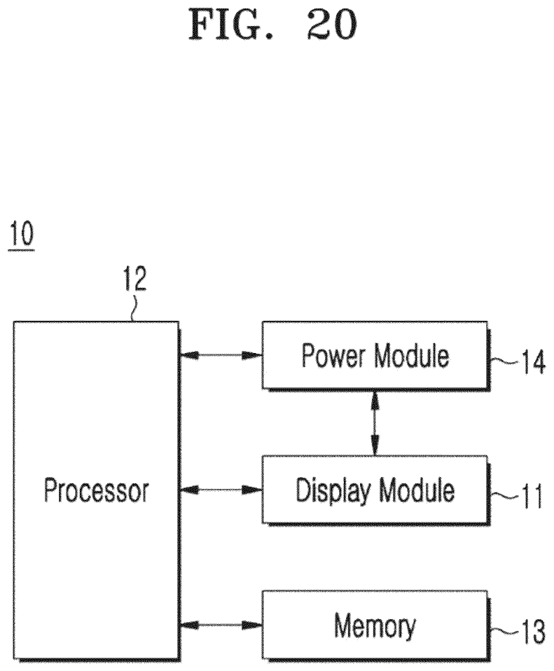

FIG. 20 is a block diagram of an electronic device according to an embodiment.

Referring to FIG. 20, an electronic device 10 according to an embodiment may include a display module 11, a processor 12, a memory 13, and a power module 14.

The processor 12 may include a central processing unit (CPU), an application processor (AP), a graphics processing unit (GPU), a communication processor (CP), an image signal processor (ISP), and/or a controller.

The memory 13 may store data information necessary or useful for the operation of the processor 12 and/or the display module 11. If (e.g., when) the processor 12 executes an application stored in the memory 13, an image data signal and/or an input control signal may be transmitted to the display module 11 and the display module 11 may process the received signal and output image information through a display screen.

The power module 14 may include a power supply module such as a power adapter and/or a battery device, and a power conversion module that converts the power supplied by the power supply module to generate power necessary or useful for the operation of the electronic device 10.

At least one of the components of the electronic device 10 described above may be included in the display device according to embodiments described above. Also, some of the individual modules functionally included in one module may be included in the display device, and some others thereof may be provided separately from the display device. For example, the display module 11 may include the display device, and the processor 12, the memory 13, and the power module 14 may be provided in the form of other devices in the electronic device 10 that is not the display device.

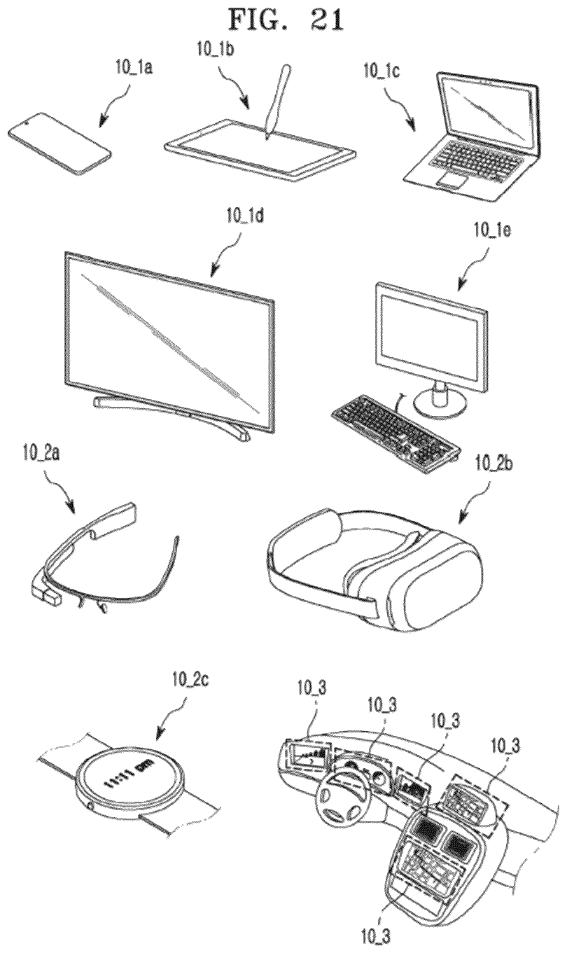

FIG. 21 is a schematic diagram of electronic devices according to embodiments.

Referring to FIG. 21, examples of various suitable electronic devices including the display device according to embodiments described above may include an electronic device to display images, such as a smartphone 10_1a, a tablet PC 10_1b, a laptop computer 10_1c, a television (TV) 10_1d, or a desk monitor 10_1e; a wearable electronic device including a display module, such as smart glasses 10_2a, a head-mounted display 10_2b, or a smart watch 10_2c; and a vehicle electronic device 10_3 including a display module, such as a room mirror display and/or a center information display (CID) provided in the instrument panel, center fascia, and/or dashboard of a car. The electronic device may also include virtual reality glasses and/or augmented reality glasses.

Hereinafter, experimental examples including embodiments and comparative examples are presented to help understanding of the subject matter of the disclosure; however, these embodiments are merely illustrative of embodiments of the disclosure and do not limit the scope of the appended claims, and it will be apparent to those of ordinary skill in the art that various suitable changes and modifications may be made to the embodiments within the scope and concept of the disclosure, and it will be natural that such changes and modifications fall within the scope of the appended claims, and equivalents thereof.

### EMBODIMENT

A pixel definition layer PDL is formed as illustrated in FIGS. 7 to 11.

For example, a polyimide resin (DL-1001D, Toray Corporation) composition was applied as a first photosensitive resin to form a lower insulating layer LIL (e.g., a lower electrically insulating layer LIL). An acrylic resin (NPAR-526, Nissan Corporation) composition was used as a second photosensitive resin to form an upper insulating layer UIL (e.g., an upper electrically insulating layer UIL) over the lower insulating layer LIL.

A photomask was provided over the upper insulating layer UIL, and it was exposed with an irradiation amount of 200 mJ/cm² and developed with a potassium hydroxide (KOH) solution. Thereafter, the lower insulating layer LIL and the upper insulating layer UIL were post-baked together at 150 °C to form the pixel definition layer PDL of FIG. 11.

### Comparative Example

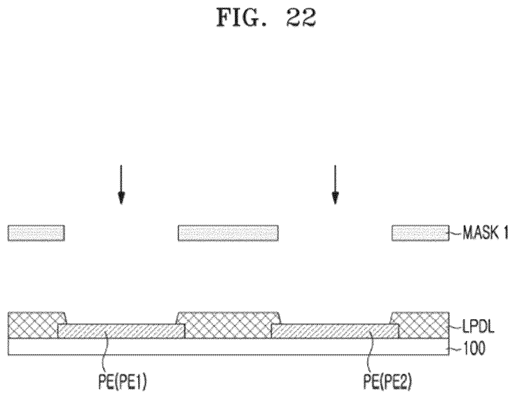

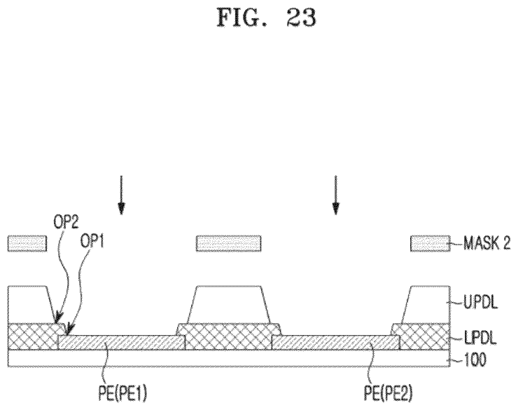

FIGS. 22 and 23 are schematic cross-sectional views illustrating a method of manufacturing a pixel definition layer PDL according to a comparative example.

For example, a lower insulating layer LIL (e.g., a lower electrically insulating layer LIL) was formed, and it was exposed, developed, and cured with a first photomask MASK 1 to form a lower pixel definition layer LPDL including an opening OP1 (e.g., FIG. 22). Thereafter, an upper insulating layer UIL (e.g., an upper electrically insulating layer UIL) was formed over the lower pixel definition layer LPDL, and it was exposed, developed, and cured with a second photomask MASK 2 to form an upper pixel definition layer UPDL including an opening OP2 over the lower pixel definition layer LPDL (e.g., FIG. 23).

### Evaluation Example

### (1) XRR Evaluation

With respect to the pixel definition layers PDL according to the embodiment and the comparative example, the thickness (Å) and roughness (Å) of the interface layer INT were measured by using an XRR measuring device (D8 ADVANCE Plus, Bruker Corporation).

For example, an XRR analysis was performed under the conditions of an X-ray wavelength of 1.54 Å, a slit width of 0.1 mm, a voltage of 40 kV, and a current of 40 mA.

The results thereof are shown in Table 1.

TABLE 1

Interface layer (INT) characteristics

| Sort | Thickness (Å) | Roughness (Å) |
|---|---|---|
| Embodiment | 35.5 | 3.3 |
| Comparative | 5.1 | 1 |
| example | | |

### (2) Morphology Evaluation

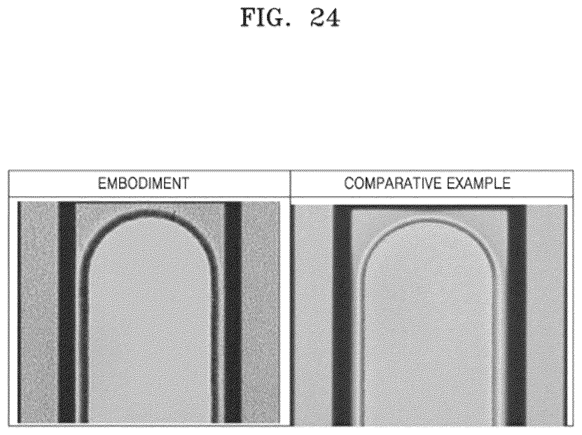

With respect to the pixel definition layers according to the embodiment and the comparative example, surface images of the pixel definition layers PDL were obtained by using an optical microscope and the images are shown in FIG. 24.

FIG. 24 is a surface image of pixel definition layers according to an embodiment and a comparative example.

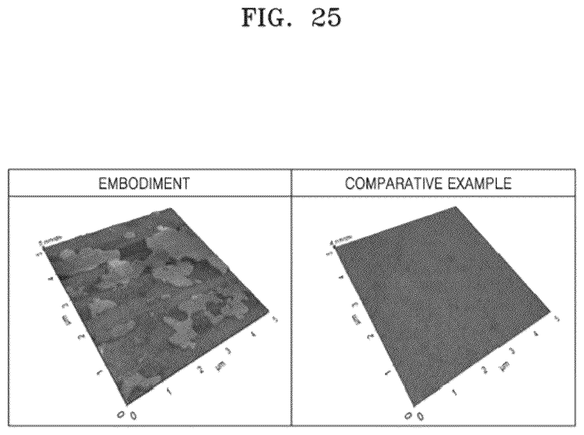

Also, an atomic force microscopy (AFM) analysis was performed on the pixel definition layers according to the embodiment and the comparative example to obtain images representing the surface contact angles of the pixel definition layers PDL and the images are shown in FIG. 25.

FIG. 25 is an image illustrating surface contact angles of pixel definition layers according to an embodiment and a comparative example.

Referring to FIGS. 24 and 25, in the embodiment, the roughness of the pixel definition layer interface was adjusted to about 1.5 Å to about 20 Å, and thus, the wrinkle of the upper pixel definition layer surface increased and the surface contact angle increased.

In the comparative example, the pixel definition layer surface was observed as being smooth and the surface contact angle decreased.

### (3) Repellency Evaluation

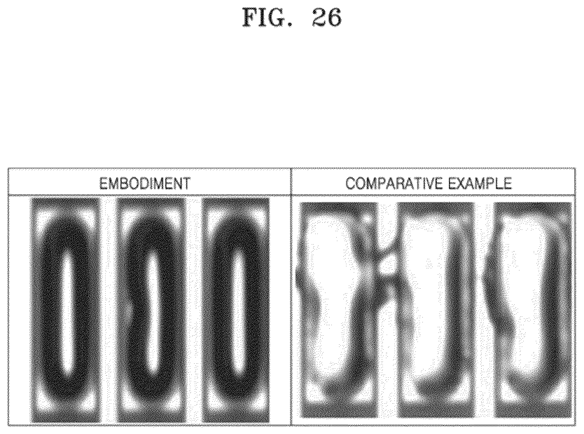

An organic light emitting material (ink) was applied over the pixel definition layers according to the embodiment and the comparative example, and surface images thereof were obtained by using an optical microscope and are shown in FIG. 26. The repellency of the pixel definition layer PDL was evaluated by identifying whether the ink overflows.

FIG. 26 is an image illustrating surface repellencies of pixel definition layers according to an embodiment and a comparative example.

Referring to FIG. 26, in the embodiment, the ink drops were stably provided in the opening.

In the comparative example, the residue of the ink on the surface of the pixel definition layer PDL increased.

A display device according to embodiments may include a pixel definition layer having a multilayer structure. The pixel definition layer may include an upper pixel definition layer, a lower pixel definition layer, and an interface between the upper pixel definition layer and the lower pixel definition layer and having a set or certain roughness. Thus, the pixel definition layer may have improved repellency.

In a method of manufacturing a display device according to embodiments, a lower insulating layer (e.g., a lower electrically insulating layer) and an upper insulating layer (e.g., an upper electrically insulating layer) may be sequentially formed and then concurrently (e.g., simultaneously) exposed/developed to form a pixel definition layer. Accordingly, if (e.g., when) a light emitting unit is formed over a pixel electrode, an organic light emitting material may be stably applied in a pixel area.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A display device comprising:
a base substrate;
a transistor structure provided over the base substrate;
a pixel electrode electrically connected to the transistor structure over the base substrate;
a pixel definition layer having an opening overlapping the pixel electrode over the base substrate, and comprising:
a lower pixel definition layer comprising a first photosensitive resin;
an upper pixel definition layer stacked over the lower pixel definition layer and comprising a second photosensitive resin that is different from the first photosensitive resin; and
an interface layer between the lower pixel definition layer and the upper pixel definition layer and having a roughness of about 1.5 Å to about 20 Å, as measured by X-ray reflectometry,
a light emitting unit provided over the pixel definition layer and the pixel electrode; and
an opposite electrode provided over the light emitting unit.

2. The display device of claim 1, wherein the roughness of the interface layer, as measured by the X-ray reflectometry, is about 2 Å to about 10 Å.

3. The display device of claim 1, wherein a thickness of the interface layer, as measured by the X-ray reflectometry, is about 10 Å to about 200 Å.

4. The display device of claim 1, wherein a thickness of the interface layer, as measured by the X-ray reflectometry, is about 20 Å to about 100 Å.

5. The display device of claim 1, wherein the interface layer comprises a blend of the first photosensitive resin and the second photosensitive resin.

6. The display device of claim 1, wherein the first photosensitive resin comprises a polyimide resin.

7. The display device of claim 1, wherein the second photosensitive resin comprises an acrylic resin.

8. The display device of claim 1, wherein the pixel definition layer comprises a wrinkle structure provided at each of an upper surface of the upper pixel definition layer and a side surface of the upper pixel definition layer.

9. The display device of claim 8, wherein the wrinkle structure is not provided at a side surface of the lower pixel definition layer.

10. The display device of claim 1, wherein a side surface of the upper pixel definition layer and a side surface of the lower pixel definition layer are on a same plane in the opening.

11. The display device of claim 10, wherein the side surface of the upper pixel definition layer, the side surface of the lower pixel definition layer, and a side surface of the interface layer are on a same plane in the opening.

12. A method of manufacturing a display device, the method comprising:
forming a pixel electrode over a base substrate;
forming a lower insulating layer by applying a first photosensitive resin composition to cover the pixel electrode;
forming an upper insulating layer by applying a second photosensitive resin composition over the lower insulating layer;
forming an exposed portion and a non-exposed portion in each of the upper insulating layer and the lower insulating layer by partially exposing the upper insulating layer and the lower insulating layer together;
forming an opening exposing an upper surface of the pixel electrode, by removing the exposed portions or the non-exposed portions included in the upper insulating layer and the lower insulating layer together;
forming a light emitting unit over the pixel electrode; and
forming an opposite electrode over the light emitting unit.

13. The method of claim 12, wherein the forming of the lower insulating layer comprises forming a first pre-cured layer by pre-baking the applied first photosensitive resin composition.

14. The method of claim 12, wherein the forming of the upper insulating layer comprises forming a second pre-cured layer by pre-baking the applied second photosensitive resin composition.

15. The method of claim 12, wherein an interface layer is formed between the lower insulating layer and the upper insulating layer as the second photosensitive resin composition is applied over the lower insulating layer.

16. The method of claim 12, further comprising, after the forming of the opening, post-baking the upper insulating layer and the lower insulating layer with the exposed portion or the non-exposed portion removed therefrom, together.

17. The method of claim 16, wherein the post-baking comprises forming an upper pixel definition layer and a lower pixel definition layer from the upper insulating layer and the lower insulating layer with the exposed portion or the non-exposed portion removed therefrom, respectively.

18. The method of claim 17, wherein the post-baking comprises forming a wrinkle structure at each of an upper surface of the upper pixel definition layer and a side surface of the upper pixel definition layer.

19. The method of claim 12, wherein the first photosensitive resin composition and the second photosensitive resin composition comprise a same solvent.

20. An electronic device comprising:
a display device;
a memory; and
a processor configured to control an operation of the display device by executing data included in the memory, wherein the display device comprises:
a base substrate;
a transistor structure provided over the base substrate;
a pixel electrode electrically connected to the transistor structure over the base substrate;
a pixel definition layer having an opening overlapping the pixel electrode over the base substrate, and comprising:
a lower pixel definition layer comprising a first photosensitive resin;
an upper pixel definition layer stacked over the lower pixel definition layer and comprising a second photosensitive resin that is different from the first photosensitive resin; and an interface layer between the lower pixel definition layer and the upper pixel definition layer and having a roughness of about 1.5 Å to about 20 Å, as measured by X-ray reflectometry;
a light emitting unit provided over the pixel definition layer and the pixel electrode; and
an opposite electrode provided over the light emitting unit.
